(19) United States
(12) Patent Application Publication
(10) Pub. No.: US 2022/0373508 A1
(43) Pub. Date: Nov. 24, 2022

(54) ORGANIC ELECTROCHEMICAL TRANSISTOR FOR BIOLOGICAL ELEMENT

(71) Applicant: OMINI, Saint-Mandé (FR)

(72) Inventors: Joanne KANAAN, Puteaux (FR); Anna SHIRINSKAYA, Paris (FR)

(73) Assignee: OMINI, Saint-Mandé (FR)

(21) Appl. No.: 17/763,315

(22) PCT Filed: Sep. 30, 2020
(86) PCT No.: PCT/EP2020/077313

§ 371 Date: Mar. 24, 2022

(30) Foreign Application Priority Data
Sep. 30, 2019 (EP) 19306229.6

(51) Int. Cl. G01N 27/414; H01L 51/05; H01L 51/10

(52) U.S. Cl. CPC G01N 27/4145; H01L 51/0558; H01L 51/107

(57) ABSTRACT

An organic electrochemical transistor including a source and drain connected by a conductive channel, a gate electrically connected to the conductive channel via an ionically stable layer, and a biological recognition layer in direct contact with the gate. The organic electrochemical transistor can be used to measure the concentration of a biological element in a biological sample. Also, an electronic device including the organic electrochemical transistor.

### FIELD OF INVENTION

The present invention pertains to the field of biological sensing. In particular, the invention relates to an organic electrochemical transistor comprising source and drain connected by a conductive channel, and a gate electrically connected to the conductive channel via an ionically stable layer.

### BACKGROUND OF INVENTION

In the field of biological sensing, organic electrochemical transistors (OECT) are of particular interest. An OECT is a transistor in which the drain current is controlled by the injection of ions from an electrolyte into a semiconductor channel, such as a polymer film. The injection of ions in the drain channel can be controlled by the voltage of the gate electrode.

In their article “Label-free and selective single-molecule bioelectronic sensing with a millimeter-wide self-assembled monolayer of anti-immunoglobulins”, Chem. Mater., DOI: 10.1021/acs.chemmater.8b04414, authors describe how to detect a biological element (i.e. an immunoglobulin M) with an OECT whose gate has been functionalized with anti-immunoglobulin. High sensitivity (i.e. single molecule) and selectivity are obtained.

However, such device is very sensitive to ionic content of sample to be analyzed. In particular, for real samples such as blood, serum, sweat, urine or saliva, ionic elements, especially salts may be injected in channel, resulting in lower sensitivity or instable results.

Sensitivity to real biological samples of OECT biological sensors needs to be lowered, so as to have reliable measurements.

Surprisingly, applicant has found that using an ionically stable layer in an OECT provides with improved reliability of measurements, in particular to obtain a device whose accuracy doesn't depend on biological sample diversity.

### SUMMARY

This invention thus relates to an organic electrochemical transistor (OECT) comprising source and drain connected by a conductive channel, and a gate electrically connected to the conductive channel via a water immiscible ionic liquid layer, and a biological recognition layer in direct contact with the gate.

In particular, the anionic part of the water immiscible ionic liquid may be selected from hexafluorophosphate (PF6-), bis(trifluoro-methylsulfonyl)imide (Tf2N-), ethyl sulfate (EtSO4-), bis(trifluoromethylsulfonyl)imide (TFSI), tetrafluoroborate (BF4-), prolinate (Pro) and N-trifluoromethylsulfonyl-L-leucine (Tf-Leu). Besides, the cationic part of the water immiscible ionic liquid may be selected from 1-alkyl-3-methylimidazolinium [CnMIM], in particular compounds with branched or linear alkyl such as 1-ethyl-3-methylimidazolium (C2MIM), 1-butyl-3-methylimidazolium (BMIM), 1-hexyl-3-methylimidazolium (BMIM), 1-octyl-3-methylimidazolium (BMIM), 1-decyl-3-methylimidazolium (DMIM); 1-butyl-3-methylsilylimidazolium (C4(C1C1C1Si)IM), 1, 3-diethylimidazolium (C2C2IM); 1-propyl-3-methylpiperidinium (C3CIPIP); 3-(2-(Butylamino)-2-oxoethyl)-1-ethylimidazolium ([CH2CONHC4H9]C2IM) and tetrabutylphosphonium (P4444).

In a specific embodiment, the water immiscible ionic liquid may be selected from 1-butyl-3-methylimidazolium hexafluorophosphate ([BMIM][PF6]), 1-decyl-3-methylimidazolium bis(trifluoro-methylsulfonyl)imide ([DMIM][Tf2N]), 1-ethyl-3-methylimidazolium ethyl sulfate (C2MIM EtSo4) and (1-Ethyl-3-methylimidazolium bis(trifluoromethylsulfonyl)imide [EMIM][TFSI]

In another embodiment, the water immiscible ionic liquid layer is in direct contact with the conductive channel.

In another embodiment, the water immiscible ionic liquid layer further comprises a solid-like matrix.

In another embodiment, the biological recognition layer in direct contact with the gate comprises enzymes, enzyme-based recognition systems, antibodies, antibody fragments, antibody dendrimer conjugates, nanobodies, engineered binding proteins, receptors, lectins, aptamers, aptazymes, ssDNA, dsDNA, DNA oligomers, ssRNA, dsRNA, RNA oligomers, modified RNA, DNA/RNA hybrids, peptide nucleic acids, cells, microorganisms, biological tissues or organelles.

In another embodiment, OECT further comprises a selective membrane over the water immiscible ionic liquid layer and/or the biological recognition layer.

In a particular embodiment, OECT comprises successive layers:
i. a substrate, preferably substrate is selected from plastic, paper and glass,
ii. an electric layer on the substrate, said electric layer comprising source, drain, gate and channel, wherein channel connects source and drain,
iii. the biological recognition layer, the water immiscible ionic liquid layer and a hydrophobic layer comprising two recesses for receiving the biological recognition layer and the water immiscible ionic liquid layer on the electric layer, wherein the biological recognition layer is on gate, and wherein the water immiscible ionic liquid layer is on channel,
iv. an encapsulation layer on hydrophobic layer to prevent damage and degradation, said encapsulation layer comprising a recess above the biological recognition layer and the water immiscible ionic liquid layer.

In a variant, OECT comprises successive layers:
i. a substrate, preferably substrate is selected from plastic, paper and glass,
ii. an electric layer on the substrate, said electric layer comprising source, drain, gate and channel, wherein channel connects source and drain,
iii. the biological recognition layer, the water immiscible ionic liquid layer and a hydrophobic layer comprising two recesses for receiving the biological recognition layer and the water immiscible ionic liquid layer on the electric layer, wherein the biological recognition layer is on a part of gate, and wherein the water immiscible ionic liquid layer is on channel and optionally on a part of gate,
iv. an encapsulation layer on hydrophobic layer to prevent damage and degradation, said encapsulation layer comprising a recess above the biological recognition layer and the water immiscible ionic liquid layer.

The invention also relates to an electronic device comprising an organic electrochemical transistor according to all embodiments described above.

The invention also relates to the use of an organic electrochemical transistor according to all embodiments described above to measure in a biological sample the concentration of a biological element.

### Definitions

In the present invention, the following terms have the following meanings:
“ionically stable layer” refers to a layer whose ionic content is not modified by surrounding medium.
“ionic liquid”: refers to low melting point salts (i.e. below the normal boiling point of water), thus forming liquids that are comprised entirely of cations and anions.
“ionogel”: refers to a mixture of ionic liquid and solid-like matrix and having gel properties. Ionogel has the same properties of diffusion of charges than ionic liquid, but convection is prevented because of viscoelastic properties. In addition, an ionogel can be manipulated cautiously as if it were solid.
“solid-like matrix”: refers to a supramolecular arrangement yielding viscoelastic properties to a liquid, so that a sample of liquid comprising a solid-like matrix may be manipulated like a solid, i.e. with a stable and definite shape, during few minutes. This supramolecular arrangement may be organic, such as polymers; inorganic, such as nanoparticles; or a mixture of organic and inorganic compounds.
“water immiscible”: refers to a solvent whose miscibility in water is very low. For ionic liquids, it corresponds to ions (anions and cations) with low interaction strength with water, i.e. with water-ion interaction strength E_{wi}>−117 kJ/mol (source: Klahn, M., Stüber, C., Seduraman, A., & Wu, P. (2010). What Determines the Miscibility of Ionic Liquids with Water? Identification of the Underlying Factors to Enable a Straightforward Prediction. The Journal of Physical Chemistry B, 114(8), 2856-2868. doi:10.1021/jp1000557).
“layer A on layer B”: a layer A that is “on” a layer B is defined as a layer that
i. is positioned above layer B
ii. is not necessarily in contact with layer B, that is to say one or more intermediate layer(s) may be interleaved between layer A and layer, and
iii. does not necessarily completely cover layer B.
“biological recognition layer”: refers to a layer which is functionalized with biological species able to interact with biological elements from a sample.
“selective membrane”: refers to a membrane which is selectively permeable to some elements of a sample. In other words, some elements may diffuse through the selective membrane whereas other elements cannot diffuse through the same selective membrane.

### DETAILED DESCRIPTION

The following detailed description will be better understood when read in conjunction with the drawings. For the purpose of illustrating, the organic electrochemical transistor is shown in the preferred embodiments. It should be understood, however that the application is not limited to the precise arrangements, structures, features, embodiments, and aspect shown. The drawings are not drawn to scale and are not intended to limit the scope of the claims to the embodiments depicted. Accordingly, it should be understood that where features mentioned in the appended claims are followed by reference signs, such signs are included solely for the purpose of enhancing the intelligibility of the claims and are in no way limiting on the scope of the claims.

This invention relates to an organic electrochemical transistor comprising source (2S) and drain (2D) connected by a conductive channel (3), and a gate (2G) electrically connected to the conductive channel (3) via an ionically stable layer (6).

Electrodes may have various dimensions, depending on size and precision constraints. Source and drain electrodes may have lateral dimensions (length and width) in the range of 100 nm to 2 cm, preferably in the range of 1 μm to 1.5 cm, more preferably in the range of 50 μm to 1 cm. Gate electrode may have lateral dimensions (length and width) in the range of 100 nm to 5 cm, preferably in the range of 1 μm to 3 cm, more preferably in the range of 50 μm to 2 cm.

Surface of electrodes is typically in the range of 1 mm² to 100 mm². Surface of channel is typically in the range of 0.1 mm² to 10 mm².

In the invention, two elements are electrically connected when a continuous path through conductive mediums exists between said two elements.

FIG. 1 illustrates a schematic of an organic electrochemical transistor (OECT). OECT includes gate electrode (2G), channel (3), which typically can include a semiconductor film (e.g., a conjugate polymer film), source electrode (2S) and drain electrode (2D). Source electrode (2S) and drain electrode (2D) can establish electrical contact to channel (3), while gate electrode (2G) establishes electrical connection with channel (3) through an electrolyte medium.

Channel (3) may consist of a conjugate polymer in either intentionally doped or pristine form with electrochemical doping/dedoping properties. Conjugate polymer layer may conduct holes (p-type) or electrons (n-type).

Conjugate polymers may be composed of planar, rigid aromatic repeating units that typically template an extended ribbonlike macromolecular conformation, such as polypyrrole, polyaniline, and polythiophene derivatives such as doped poly(3,4-ethylenedioxythiophene) (PEDOT).

Polypyrrole could be used in its pristine form or doped by various dopants, such as paratoluene-2-sulfonic acid (PTSA), sodium dodecylbenzene sulfonate (SDBS) or sodium dodecyl sulfate SDS.

Polyaniline could be also used in a doped form (with phytic acid or HCl)

Poly(3,4-ethylenedioxythiophene) could be doped with various dopants, including chloride anions as well as small molecular anions such as tosylate, biodopants (negatively charged biomolecular agents such as synthetic lipids, sugars, and laminin peptides and even living cells) and polyanions such as polystyrene sulfonate (PSS).

PEDOT:S is such a conjugate polymer with pendant sulfonate groups anchored onto the PEDOT backbone.

Among n-type conductors following conjugate polymers may be used: polypyrrole; polyaniline; poly(2-(3,3′-bis(2-(2-(2-methoxyethoxy)ethoxy)ethoxy)-[2,2′-bithiophen]-5-yl)thieno[3,2-b]thiophene) (p(g2T-TT)); (co-3,3′-bis(2-(2-(2-methoxyethoxy)ethoxy)ethoxy)-(bithiophene))) p(gNDI-g2T); perylenediimide (PDI), functionalized with dioctyl side chains (i.e., N,N′-dioctyl-3,4,9,10-perylene tetracarboxylic diimide (PTCDI-C8)); Poly{I[N,N′-bis(2-octyldodecyl)-naphthalene-1,4,5,8-bis(dicarboximide)-2,6-diyl]-alt-5,5′-(2,2′-bithiophene)} (P(NDI20D-T2)) and ladder-type polymers such as Poly(benzimidazobenzophenanthroline) (BBL).

Among p-type conductors following conjugate polymers may be used: poly(3,4-ethylenedioxythiophene) polystyrene sulfonate (PEDOT:PSS); self-doped poly(3,4-ethylenedioxythiophene) (PEDOT-S); Tetrabutylammonium poly(6-(thiophen-3-yl)hexane-1-sulfonate) (PTHS).

Preferred conjugate polymers are polypyrrole; polyaniline; PEDOT:PSS; PEDOT-S; PTHS; p(g2T-TT) and p(gNDI-g2T).

The electrolyte medium may comprise several separated electrolyte domains. The biological sample under analysis, in which a biological element is looked for, is one electrolyte domains. The ionically stable layer (6) is one electrolyte domain. Other electrolyte domains may be present.

The electrolyte domain which is in direct contact with channel (3) behaves like an ion reservoir. When voltage of gate (2G) varies after interaction with the biological element to be analyzed, ions from reservoir are injected in or withdrawn from channel (3), change electronic charge density of channel (3) and finally change the drain (2D) current which is measured by a usual electronic device. Drain (2D) current is finally a measure of gate (2G) voltage, which is an indication of presence of biologic element interacting with biological recognition layer (5).

In order to improve accuracy of measurement, ions from the sample under analysis should not be able to transfer in channel (3). Ionically stable layer (6) has an ionic composition which is not modified by sample under analysis. Hence, very different samples may be analyzed with the same OECT without having bias, variability or instability linked to the specific composition of sample under analysis.

In this disclosure, the ionically stable layer comprises a water immiscible ionic liquid, thus forming a water immiscible ionic liquid layer. Ionic liquids are liquids that are comprised entirely of cations and anions. Hence, an ionic liquid is a charge reservoir able to inject charges in channel or withdraw charges from channel, enabling electric measurement. In addition, a water immiscible medium behaves like a barrier for aqueous based species. In particular, ions such as Sodium or Potassium or charged biologic elements such as proteins or cells will not be able to diffuse through ionic liquid. Indeed, a water immiscible ionic liquid is simultaneously a charge reservoir and a barrier to water soluble charged species.

By water immiscible ionic liquid, it is meant that ions, i.e. anions and cations, that constitutes ionic liquid have a low interaction strength with water E_{wi}, namely E_{wi}>−117 kJ/mol.

According to a first configuration, channel is a n-doped semiconductor material, i.e. a material in which electric free charges are electrons. In this configuration, negative ions from the water immiscible ionic liquid will be injected in channel or withdrawn from channel. The anionic part of the water immiscible ionic liquid may be selected from hexafluorophosphate (PF6-), bis(trifluoro-methylsulfonyl)imide (Tf2N-), ethyl sulfate (EtSO4-), bis(trifluoromethylsulfonyl)imide (TFSI), tetrafluoroborate (BF4-), prolinate (Pro) and N-trifluoromethylsulfonyl-L-leucine (Tf-Leu).

According to a second configuration, channel is a p-doped semiconductor material, i.e. a material in which electric free charges are holes. In this configuration, positive ions from the water immiscible ionic liquid will be injected in channel or withdrawn from channel. The cationic part of the water immiscible ionic liquid may be a 1-alkyl-3-methylimidazolium, preferably the cationic part of the water immiscible liquid is selected from 1-ethyl-3-methylimidazolium (C2MIM), 1-butyl-3-methylimidazolium (BMIM), 1-hexyl-3-methylimidazolium (BMIM), 1-octyl-3-methylimidazolium (BMIM), 1-decyl-3-methylimidazolium (DMIM). The cationic part of the water immiscible ionic liquid may be also selected from 1-butyl-3-methylsilylimidazolium (C4(C1C1C1Si)IM), 1, 3-diethylimidazolium (C2C2IM), 1-propyl-3-methylpiperidinium (C3C1PIP), 3-(2-(Butylamino)-2-oxoethyl)-1-ethylimidazolium ([CH2CONHC4H9]C2IM) and tetrabutylphosphonium (P4444).

In a particularly suitable configuration, water immiscible ionic liquid may be selected from 1-butyl-3-methylimidazolium hexafluorophosphate ([BMIM][PF6]), 1-decyl-3-methylimidazolium bis(trifluoro-methylsulfonyl)imide ([DMIM][Tf2N]), 1-ethyl-3-methylimidazolium ethyl sulfate (C2MIM EtSo4) and (1-Ethyl-3-methylimidazolium bis(trifluoromethylsulfonyl)imide [EMIM][TFSI].

According to another embodiment, the ionically stable layer (6) is in direct contact with the conductive channel. This configuration allows for a compact device and improves charges injection or withdrawal, yielding an improved stability of measurement.

According to another embodiment, the ionically stable layer (6) further comprises a solid-like matrix. In other words, the ionically stable layer (6) is a composite layer comprising a solid-like matrix. In particular, the ionically stable layer (6) may be a composite layer comprising a solid-like matrix and a water immiscible ionic liquid, forming an ionogel. The solid-like matrix brings to the ionically stable layer some mechanical resistance, which is desirable during preparation of OECT: laying the ionically stable layer (6) is easier and more precise; and during use of OECT: ionically stable layer (6) is more resistant to mechanical constraints and OECT has an improved time life. Solid-like matrix may be an organic polymer, such as polyethylene oxide, polymethylmethacrylate (PMMA) or cellulose derivatives; an inorganic material, such as carbon nanotubes or silica; or an organic-inorganic composite, such as silsesquioxane or materials obtained by sol-gel reaction of silanes.

In the ionically stable layer (6), solid-like matrix may represent from 1% to 99% of weight. In particular, solid-like matrix weight percentage may be 2, 3, 4, 5, 6, 7, 8, 9, 10, 12, 15, 20, 25, 30, 40, 50, 60, 70, 80.

In the ionically stable layer (6), water immiscible ionic liquid may represent from 1% to 99% of weight. In particular, water immiscible ionic liquid weight percentage may be 99, 98, 97, 96, 95, 94, 93, 92, 91, 90, 88, 85, 80, 75, 70, 60, 50, 40, 30, 20. Preferably, the water immiscible ionic liquid is a continuous phase in the ionically stable layer (6).

In an embodiment, the ionically stable layer (6) is not a UV cured or heat cured material. In other words, the ionically stable layer (6) is not obtained by UV curing or heat curing of a polymerizable composition comprising an ionic liquid, yielding a polymer acting as a solid-like matrix in contact with ionic liquid.

In this disclosure, OECT comprises a biological recognition layer (5) in direct contact with the gate (2G). Such functionalization of the gate (2G) allows for specific sensing of biological elements in the sample under analysis. Indeed, association of the target biological element with functionalized gate (2G) changes electric potential of gate (2G), yielding an electric signal in OECT. Gate (2G) may be functionalized by enzymes, enzyme-based recognition systems, antibodies, antibody fragments, antibody dendrimer conjugates, nanobodies, engineered binding proteins, receptors, lectins, aptamers, aptazymes, ssDNA, dsDNA, DNA oligomers, ssRNA, dsRNA, RNA oligomers, modified RNA, DNA/RNA hybrids, peptide nucleic acids, cells, microorganisms, biological tissues or organelles.

According to another embodiment, OECT comprises a selective membrane (8) over the ionically stable layer (6) and/or the biological recognition layer (5). Such membrane provides with an additional separation between OECT and sample under analysis. In particular, such membrane may be useful with blood samples, so that only plasma can get in contact with biological recognition layer (5) and/or the ionically stable layer (6). The latter are less polluted and thus, response and signal-to-noise ratio of OECT is improved. Suitable selective membranes (8) are commercially available LF1, MF1, VF1 and VF2 from Whatman International Ltd. (Maidstone, England).

According to a specific embodiment, OECT comprises successive layers.

A substrate (1) is provided as a support. Preferably substrate (1) is selected from plastic, paper and glass.

An electric layer is on the substrate (1). Electric layer comprises source (2S), drain (2D), gate (2G) and channel (3). Channel (3) connects source (2S) and drain (2D). Source (2S), drain (2D) and gate (2G) are metallic or non-metallic electrodes deposited on the substrate. Gold and its alloys are particularly suitable for electrodes.

The biological recognition layer (5), the ionically stable layer (6) and a hydrophobic layer (4) comprising two recesses for receiving the biological recognition layer (5) and the ionically stable layer (6) are on the electric layer. The biological recognition layer (5) is on gate (2G), and the ionically stable layer (6) is on channel (3). In an embodiment, the biological recognition layer (5) covers completely gate (2G). In another embodiment, the ionically stable layer (6) covers completely channel (3). Hydrophobic layer (4) is a thin layer (from dozen of nanometers up to hundreds of micrometers) of hydrophobic or super-hydrophobic coating, deposited on the electric layer. Hydrophobic layer (4) may be deposited by inkjet or as a dispersion then allowed to dry or may be reported, i.e. a hydrophobic film is first cut then laid on the electric layer. Hydrophobic layer (4) may be organic or inorganic. Organic materials are highly processable and include polymeric and non-polymeric materials. Polymeric materials may be Polyacrylics, Polyamides and Polyimides, Polycarbonates, Polydienes, Polyesters, Polyethers, Polyfluorocarbons, Polyolefins, Polystyrenes, Polyvinyl acetals, Polyvinyl and Polyvinylidene chlorides, Polyvinyl esters, Polyvinylpyridine and Polyvinypyrrolidone polymers. Non-polymeric materials may be silanes (ex. fluorinated silanes). Inorganic materials provide with high stability and may be precipitated calcium carbonate, carbon nano-tube structures, silica nano-coating or composite materials such as manganese oxide polystyrene (MnO2/PS) nano-composite, zinc oxide polystyrene (ZnO/PS) nano-composite.

The encapsulation layer (7) is on hydrophobic layer (4) and comprises a recess above the biological recognition layer (5) and the ionically stable layer (6) to prevent damage and degradation. Various materials may be used as encapsulation layer, in particular polymer materials with dielectric constant less than four, such as Kapton® film (polyimide), DuPont PI 2611 polyimide, Benzocyclobutene polymers (BCB) and epoxies.

All the layers above may be deposited by any suitable physical or chemical method including inkjet printing, roll-to-roll, spin coating and vacuum deposition.

In this specific embodiment, gate (2G) is electrically connected to channel (3) through three successive conductive media: biological recognition layer (5), sample (Sam) and ionically stable layer (6).

FIG. 2 illustrates OECT during testing of a blood droplet (Sam).

In a variant shown in FIG. 3, gate (2G) is virtually separated in two parts. On part is covered by biological recognition layer (5). Another part of the gate (2G) is optionally covered by ionically stable layer (6), the latter being also on the channel (3). In this variant, gate potential is modified by interactions in biological recognition layer and gate potential influences channel through ionically stable layer. Here, gate (2G) is a floating electrode, i.e. not connected with reference potential of source electrode.

The invention also relates to an electronic device comprising an organic electrochemical transistor according to any embodiment described above. The electronic device further comprises all electrical elements required to impose potential differences between electrodes, measure current flows, acquire and analyze signals.

In a particular embodiment, a reference electrode (not shown) may be included to the device. This reference electrode is functionalized with a neutral protein, such as bovine serum albumin. When device is put in contact with a sample, for instance a biological fluid of interest, reference electrode provides with a normalized signal, i.e. not sensitive to any specific biological element. This reference allows to eliminate noise and improve precision of the electronic device.

The invention also relates to the use of an organic electrochemical transistor to measure in a biological sample the concentration of a biological element. Any embodiment of the organic electrochemical transistor of the invention is suitable for this use.

Organic electrochemical transistor of the invention is particularly suitable for testing blood, saliva, urine and other biological fluid in particular to detect presence of proteic markers, cells and simple molecules in said samples.

While various embodiments have been described and illustrated, the detailed description is not to be construed as being limited hereto. Various modifications can be made to the embodiments by those skilled in the art without departing from the true spirit and scope of the disclosure as defined by the claims.

### BRIEF DESCRIPTION OF THE DRAWINGS

FIG. 1 shows an exploded view of an organic electrochemical transistor with substrate (1), source (2S), drain (2D), gate (2G), channel (3), hydrophobic layer (4), biological recognition layer (5), ionically stable layer (6), encapsulation layer (7) and selective membrane (8).

FIG. 2 shows an organic electrochemical transistor in contact with a blood droplet (Sam). Blood droplet is in contact with biological recognition layer as well as with ionically stable layer and establishes electric connection between electrodes. Hydrophobic layer, encapsulation layer and selective membrane are omitted.

FIG. 3 shows a variant in which gate (2G) is partly covered with biological recognition layer (5) under a blood droplet (Sam) and partly covered with ionically stable layer (6). Hydrophobic layer, encapsulation layer and selective membrane are omitted.

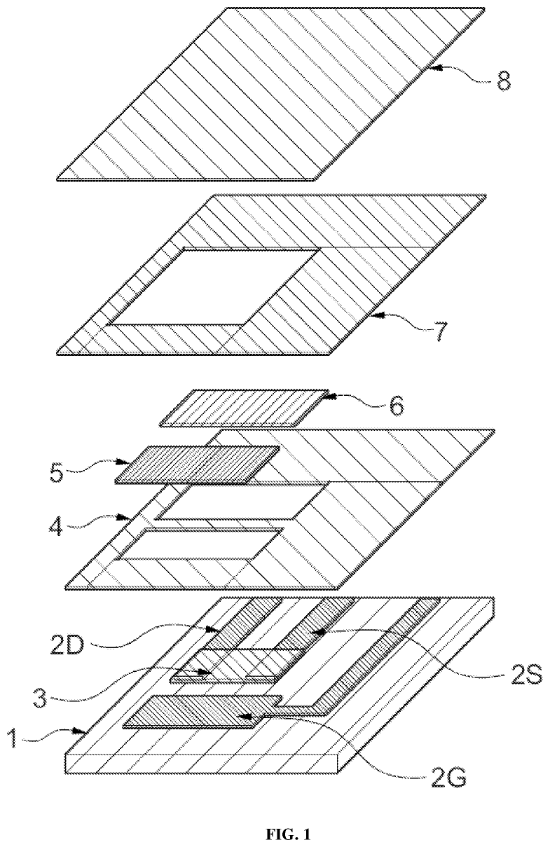

### EXAMPLES

The present invention is further illustrated by the following examples.

Preparation of OECT—Electrodes (2D), (2S) and (2G):

A glass substrate (1) is cleaned with acetone for 10 minutes then with isopropanol for 10 minutes then dried.

OECT-1: An ink containing silver (50-60% in weight of nanoparticles in tetradecane—Supplier Sigma Aldrich—Reference 736511) is deposited on glass substrate with a dimatix printer, according to drain (2D), source (2G) and gate (2G) geometry. Ink is then baked at 450° C. for 1 hour. Three electrodes are obtained. Distance between drain and source is 300 micrometer.

OECT-2: A polymeric mask is applied on glass substrate, so as to define drain (2D), source (2G) and gate (2G) geometry. Then, a 10 nm thick layer of Chromium (Cr) is evaporated under vacuum, followed by a 100 nm thick layer of Gold (Au).

Preparation of OECT—Channel (3):

An ink comprising 95.5% wt of PEDOT:PSS, 0.5% wt of dodecylbenzenesulfonic acid (DBSA) and 4% wt of ethylene glycol is prepared. With an ink-jet printer, ink is deposited on source (2D), between source (2D) and drain (2D), and on drain (2D) forming the channel (3). After printing, ink is baked at 120° C. for 1 hour. A channel having a length of 500 micrometers (on and between source and drain) and width of 4 mm.

Preparation of OECT—Hydrophobic Layer (4):

A hydrophobic ink is ink-jetted to yield the expected geometry. Thickness of hydrophobic layer is 5 micrometer.

Hydrophobic layer (4) defines two recesses. One recess corresponds to gate (2G) of OECT. The second recess corresponds to channel (3) of OECT.

Preparation of OECT—Biological Recognition Layer (5)

10 mM of a solution A consisting of 10:1 molar ratio of 3-mercaptopropionic acid (3-MPA) and 11-mercaptoundecanoic acid (11-MUA) in ethanol is prepared.

Gate of OECT-2 device is cleaned then immersed in solution A for 18 hours at 22° C., in the dark and under flux of nitrogen. Then gate of OECT-2 is rinsed several times with ethanol and deionized water, then dried with the flux of nitrogen. A self-assembled monolayer (SAM) is thus obtained on gate of OECT-2.

A solution B consisting of 0.2 mol/L 1-Ethyl-3-(3-dimethylaminopropyl)-carbodiimide (EDC) and 0.05 mol/L N-Hydroxysulfosuccinimide sodium salt (Sulfo-NHS) in water is prepared. EDC act as a temporary functionalization

Gate of OECT-2 covered with SAM is immersed in solution B for 2 hours at 25° C., then rinsed with Phosphate Buffer Solution. EDC reacts with free acid groups of SAM and brings a temporary functionalization.

A solution C consisting of 100 μg/mL anti-C reactive protein in Phosphate Buffer Solution (pH=7.4) is prepared.

Functionalized gate of OECT-2 is immersed in solution C for 2 hours at 25° C., then rinsed with Phosphate Buffer Solution. Anti-C reactive protein replaces EDC and binds to SAM.

A solution D consisting of 1 mol/L ethanolamine in Phosphate Buffer Solution (pH=7.4) is prepared.

Antibody functionalized gate of OECT-2 is immersed in solution D for 1 hour at 25° C., then rinsed with Phosphate Buffer Solution. Ethanolamine replaces EDC on acid sites which were not functionalized with anti-C reactive protein.

A solution E consisting of 1.5 μmol/L Bovine Serum Albumin (BSA) in Phosphate Buffer Solution (pH=7.4) is prepared.

Antibody functionalized gate of OECT-2 is immersed in solution E for 1 hour at 25° C., then rinsed with Phosphate Buffer Solution. BSA covers now all surface of OECT which was not functionalized with anti-C reactive protein. This step ensures that biological recognition layer will bind exclusively C reactive proteins. Other biological elements will not be able to accumulate on the surface and generate noise or artefacts in measures.

In all immersion steps, hydrophobic layer (4) sets limits to contact area of gate (2G) with solutions A to E.

Preparation of OECT—Water Immiscible Ionic Liquid Layer (6):

Channel of OECT-2 device is cleaned then 1-butyl-3-methylimidazolium hexafluorophosphate ([BMIM][PF6]) is deposited so as to form a 5 μm thick layer (same thickness as hydrophobic layer).

Preparation of OECT—Encapsulation Layer (7):

A Kapton® layer is used as encapsulation layer.

Measurements:

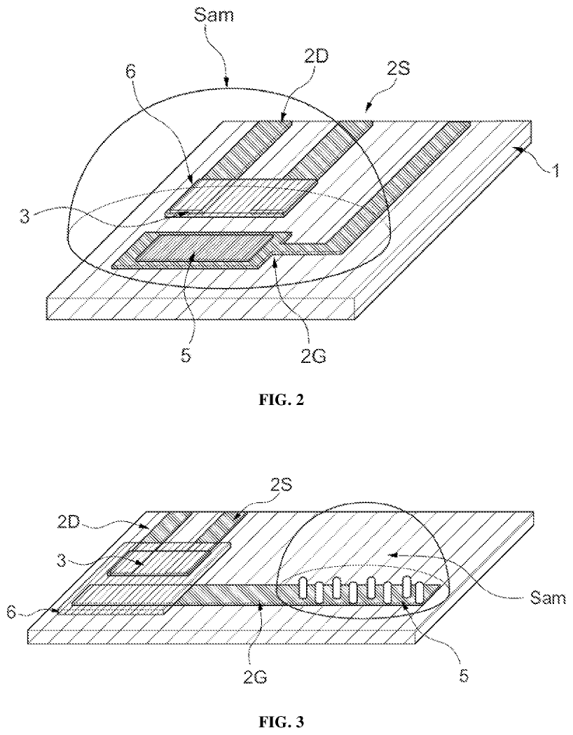

A solution of C-reactive protein at concentration of 100 mg·mL⁻¹ is prepared. A droplet of this solution is deposited on OECT, as shown in FIG. 2. The current-voltage response of OECT is measured with state-of-the-art electrical devices.

1.-12. (canceled)

13. An organic electrochemical transistor comprising source and drain connected by a conductive channel, a gate electrically connected to the conductive channel via a water immiscible ionic liquid layer, and a biological recognition layer in direct contact with the gate.

14. The organic electrochemical transistor according to claim 13, wherein the anionic part of the water immiscible ionic liquid is selected from the group of: hexafluorophosphate (PF6-), bis(trifluoro-methylsulfonyl)imide (Tf2N-), ethyl sulfate (EtSO4-), bis(trifluoromethylsulfonyl)imide (TFSI), tetrafluoroborate (BF4-), prolinate (Pro), and N-trifluoromethylsulfonyl-L-leucine (Tf-Leu).

15. The organic electrochemical transistor according to claim 13, wherein the cationic part of the water immiscible ionic liquid is selected from the group of: 1-alkyl-3-methylimidazolinium [CnMIM]; 1-propyl-3-methylpiperidinium (C3C1PIP); 3-(2-(Butylamino)-2-oxoethyl)-1-ethylimidazolium ([CH2CONHC4H9]C2IM) and tetrabutylphosphonium (P4444).

16. The organic electrochemical transistor according to claim 13, wherein the water immiscible ionic liquid is selected from the group of: 1-butyl-3-methylimidazolium hexafluorophosphate ([BMIM][PF6]), 1-decyl-3-methylimidazolium bis(trifluoro-methylsulfonyl)imide ([DMIM][Tf2N]), 1-ethyl-3-methylimidazolium ethyl sulfate (C2MIM EtSo4), and 1-Ethyl-3-methylimidazolium bis(trifluoromethylsulfonyl)imide [EMIM][TFSI].

17. The organic electrochemical transistor according to claim 13, wherein the water immiscible ionic liquid layer is in direct contact with the conductive channel.

18. The organic electrochemical transistor according to claim 13, wherein the water immiscible ionic liquid layer further comprises a solid-like matrix.

19. The organic electrochemical transistor according to claim 13, wherein biological recognition layer comprises enzymes, enzyme-based recognition systems, antibodies, antibody fragments, antibody dendrimer conjugates, nanobodies, engineered binding proteins, receptors, lectins, aptamers, aptazymes, ssDNA, dsDNA, DNA oligomers, ssRNA, dsRNA, RNA oligomers, modified RNA, DNA/RNA hybrids, peptide nucleic acids, cells, microorganisms, biological tissues or organelles.

20. The organic electrochemical transistor according to claim 19, further comprising a selective membrane over the water immiscible ionic liquid layer, over the biological recognition layer, or over both.

21. The organic electrochemical transistor according to claim 19, comprising successive layers:
(a) a substrate,
(b) an electric layer on the substrate, said electric layer comprising source, drain, gate and channel, wherein channel connects source and drain,
(c) the biological recognition layer, the water immiscible ionic liquid layer and a hydrophobic layer comprising two recesses for receiving the biological recognition layer and the water immiscible ionic liquid layer on the electric layer, wherein the biological recognition layer is on gate, and wherein the water immiscible ionic liquid layer is on channel,
(d) an encapsulation layer on hydrophobic layer to prevent damage and degradation, said encapsulation layer comprising a recess above the biological recognition layer and the water immiscible ionic liquid layer.

22. The organic electrochemical transistor according to claim 19, comprising successive layers:
(a) a substrate,
(b) an electric layer on the substrate, said electric layer comprising source, drain, gate and channel, wherein channel connects source and drain,
(c) the biological recognition layer, the water immiscible ionic liquid layer and a hydrophobic layer comprising two recesses for receiving the biological recognition layer and the water immiscible ionic liquid layer on the electric layer, wherein the biological recognition layer is on a part of the gate, and wherein the water immiscible ionic liquid layer is on channel and on a part of gate,
(d) an encapsulation layer on hydrophobic layer to prevent damage and degradation, said encapsulation layer comprising a recess above the biological recognition layer and the water immiscible ionic liquid layer.

23. An electronic device comprising an organic electrochemical transistor according to claim 13.

24. A method of measuring concentration of a biological element in a biological sample, comprising depositing a droplet of a biological sample on an organic electrochemical transistor according to claim 13.

25. The organic electrochemical transistor according to claim 1, wherein the cationic part of the water immiscible ionic liquid is a 1-alkyl-3-methylimidazolinium [CnMIM] selected from the group of: 1-ethyl-3-methylimidazolium (C2MIM), 1-butyl-3-methylimidazolium (BMIM), 1-hexyl-3-methylimidazolium (BMIM), 1-octyl-3-methylimidazolium (BMIM), 1-decyl-3-methylimidazolium (DMIM); 1-butyl-3-methylsilylimidazolium (C4(C1C1C1Si)IM); and 1, 3-diethylimidazolium (C2C2IM).
